(19) United States
(12) Patent Application Publication
(10) Pub. No.: US 2023/0367226 A1
(43) Pub. Date: Nov. 16, 2023

(54) LAYER-FORMING METHOD, OPTICAL ELEMENT AND OPTICAL SYSTEM

(71) Applicant: Carl Zeiss SMT GmbH, Oberkochen (DE)

(72) Inventors: Vitaliy SHKLOVER, Heidenheim (DE); Jeffrey ERXMEYER, Oberkochen (DE); Dirk ISFORT, Heidenheim (DE); Nils LUNDT, Schwaebisch Gmuend (DE); Barbara MOSER, Sontheim an der Brenz (DE)

(21) Appl. No.: 18/361,092

(22) Filed: Jul. 28, 2023

Related U.S. Application Data
(63) Continuation of application No. PCT/EP2022/050019, filed on Jan. 3, 2022.

(30) Foreign Application Priority Data
Jan. 28, 2021 (DE) 10 2021 200 747.3

(51) Int. Cl. G03F 7/00; C23C 14/30; C23C 14/10; C23C 14/00; H01J 37/32; G02B 1/113

(52) U.S. Cl. CPC G03F 7/7015; C23C 14/30; C23C 14/10; C23C 14/0031; H01J 37/32449; G02B 1/113; H01J 2237/332

(57) ABSTRACT

A method of forming a layer (3) on a substrate (2) made of a fluoridic material includes: depositing a coating material (9) on the substrate to form the layer and generating a plasma (12) to assist the deposition of the coating material. The plasma is formed from a gas mixture (14) containing a first gas (G) and a second gas (H), wherein the second gas has an ionization energy less than an ionization energy of the first gas, the first gas is a noble gas and the second gas is a further noble gas. An associated optical element includes: a substrate (2) composed of a fluoridic material, in particular a metal fluoride, wherein the substrate has a coating (18) having a layer (3) formed by the above method. An associated optical system, in particular for the DUV wavelength range, includes at least one such optical element.

### CROSS-REFERENCE TO RELATED APPLICATION

This is a Continuation of International Application PCT/EP2022/050019, which has an international filing date of Jan. 3, 2022, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2021 200 747.3 filed on Jan. 28, 2021.

### FIELD OF THE INVENTION

The invention relates to a method of forming at least one layer on a substrate, comprising: depositing at least one coating material on the substrate to form the layer, and generating a plasma to assist the deposition of the coating material. The invention also relates to an optical element comprising a substrate, preferably composed of a fluoridic material, in particular composed of a metal fluoride, and a coating having at least one layer formed by the method described above. The invention also relates to an optical system, in particular for the DUV wavelength range (at wavelengths of less than 250 nm), comprising at least one such optical element.

### BACKGROUND

In the context of this application, the expression “deposition on the substrate” does not necessarily mean deposition of the coating material directly on the substrate. “Deposition on the substrate” instead also means deposition of the coating material onto one or more layers already applied to the substrate.

For optical elements that are subject to high stress in the DUV/VUV wavelength range at wavelengths of less than 250 nm, in particular for microlithography and inspection systems in the semiconductor industry, fluorides are generally used as substrate material, in particular fluorspar (CaF₂) and magnesium fluoride (MgF₂). Under irradiation with high intensities, even after about 10⁶ pulses, the first damage appears on the surface of the CaF₂ material; cf. W. As a result of the interaction with the DUV/VUV radiation, local fluorine depletion occurs in the volume of such an optical element, resulting in the formation of Ca metal colloids, which themselves serve as nuclei for massive degradation. Fluorine depletion occurs even faster at the surface, where the fluorine atoms released can escape into the environment.

For example, on the outside of a laser chamber window of an excimer laser, consisting of CaF₂, degradation in the form of a white powdery coating was observed at a laser energy density of more than 20 mJ/cm². By contrast, there was no damage on the inside of the laser chamber window that was in contact with the fluorine-containing laser gas, which suggests that fluorine is the crucial substance for avoiding the deposition of the powdery coating and hence degradation. In order to avoid fluorine depletion, even a very low concentration of fluorine in the laser gas mixture is sufficient, which may, for example, be in the order of magnitude of 0.1% by volume to 0.2% by volume.

Sealing with high-density metal fluoride layers that have been sputtered (US20050023131A1, JP2003193231A1), reactively deposited (JPH11172421A1) or aftertreated (US20040006249A1, JPH11140617A1, JP2004347860A1) in a fluorine-containing atmosphere is a promising option in order to increase the radiation stability of fluoridic optics components.

However, it has been observed that, in particular in the case of metal fluoride coatings, sealing is successful only to a small degree, whereas the technological complexity required is high, since the use of plant components that are resistant to fluorine gas is inconvenient and costly. Moreover, layers produced in this way have high optical losses that are caused by the formation of color centers in fluoridic materials on account of interaction with a plasma in the case of plasma ion-assisted deposition (PIAD) or by contamination with products of the reaction of fluorine with components and walls of the coating apparatus [2].

Another method of improving radiation stability is sealing of optical elements (for example the outside of a laser chamber window) with oxides Al₂O₃ or SiO₂ or fluorinated SiO₂ (DE10350114B4, DE102006004835A1, EP1614199B1, US20030021015A1, US20040202225A1, U.S. Pat. No. 6,466,365B1, U.S. Pat. No. 6,833,949B2, U.S. Pat. No. 6,872,479B2), but fluorides in this case remain uncompacted. In order to avoid damage to fluorides by high-energy particles, EP3111257 B1 suggested an uncompacted oxidic interlayer.

For the function of optics components in optical systems, surfaces generally have to be upgraded (for example given a reflective or antireflective coating). Antireflective or reflective coating is in principle effected by applying interference layers, where two materials having a very high and very low refractive index are required. Since there are only few oxidic materials, for example SiO₂ or Al₂O₃, that are suitable in high-power applications within a wavelength range of <200 nm owing to high absorption, preference is given to using a combination of alternating fluoridic and oxidic layers (U.S. Pat. No. 9,933,711 B2, U.S. Ser. No. 10/642,167 B2). In order to avoid spectral shifts caused by moisture absorption, the aim is to achieve maximum compaction both in the case of the oxidic layers and in the case of the fluoridic layers. This can result in elevated optical losses on account of damage caused during the deposition of the layers, but these should be avoided if possible.

The packing density (also called degree of compaction hereinafter) of the coating material in an optical coating is also of relevance to the lifetime of the optical coating. The higher the degree of compaction, or the lower the porosity of the coating, in general, the better the chemical, mechanical, environmental and laser stability. In addition, the refractive index of a deposited coating material scales with the degree of compaction. The degree of compaction can be increased when the substrate is heated during the coating, for example to temperatures above about 200° C. However, performance of coating at high temperatures is not always possible, or the effect thereof is often inadequate.

A known method of compacting layers is ion or plasma ion assistance (PIAD); cf., for example, DE102005017742A1. The term “active energy per molecule (EPM)” is introduced therein. This term relates to the energy input of the ion beam which is effective in the layer growth and is normalized to the coating rate offered. The energy per molecule EPM is defined as the quotient of the product of the number Nᵢ of ions per unit time and the energy Eᵢ of the ions divided by the number N_{M} of incident coating molecules per unit time, i.e.

EPM=(Nᵢ Eᵢ)/N_{M} (1)

Since the ion energy Eᵢ has to be kept to a minimum in order that damage by high-energy ions remains low, the degree of compaction should be increased by increasing the EPM (cf. [3]). It is accordingly helpful to increase the ion current density or number of ions Nᵢ per unit time (cf. [4]) and/or to reduce the coating rate, i.e. the number N_{M} of incident coating molecules per unit time. A further aspect that has to be taken into account is the fact that the degree of compaction must remain constant over a wide range of vapor deposition angles in order that the layer grows homogeneously.

As described in DE 10 2005 017 742 A1, in most plasma sources, ion energy and ion current density are directly coupled, such that reduction in the ion energy leads to a drop in ion current density and hence to a significant drop in the effects that increase the degree of compaction. DE 10 2005 017 742 A1 therefore suggests using, for PIAD, a high-frequency plasma source as described in WO 01/163981. In the high-frequency plasma source described therein, which has a high-frequency adaptation network with a primary circuit and a secondary circuit, the active ion current density and the active ion energy are supposed to be independently adjustable, such that an optimal combination of active ion energy and active energy per molecule can be established. However, the plasma source described in WO 01/63981 is complex in terms of its production.

### SUMMARY

It is an object of the invention to provide a simplified method of forming at least one layer of an (optically active) coating, in which the coating material can be deposited with a high degree of compaction and low absorption and contamination. It is a further object of the invention to provide an optical element including a coating having at least one such layer, and an optical system having at least one such optical element.

This and other objects are achieved, in a first aspect, by a method of the type specified at the outset, in which the plasma is formed from a gas mixture containing a first gas and a second gas, wherein the second gas has an ionization energy less than an ionization energy of the first gas. The term “ionization energy” in the present application is understood to mean the 1st ionization energy of a respective chemical element or of a respective compound.

The inventors have recognized that charge carrier density and hence ion current density can be increased with the same ion energy when Penning ionization or the Penning effect is utilized in the forming of the plasma (cf. [5]). Penning ionization is a specific form of chemoionization, i.e. transfer of excitation energy in the case of particle collisions: If excited atoms of one particle type G that have greater excitation energy than the (first) ionization energy of a second particle type M occur in a gas mixture, it is then possible in the case of collision for the excitation energy of G to be transferred to M such that M is ionized:

G*+M→MG*→M⁺+e⁻+G (2)

It is not absolutely necessary here for the intermediate to dissociate, i.e. ionizations of the following type are also possible:

G*+M→MG*→MG⁺+e⁻ (3)

The Penning ionization, or the use of a suitable gas mixture, according to equation (1), thus increases the active energy per molecule EPM without increasing the active ion energy E. In this way, the coating material can be applied with a high packing density or high degree of compaction without any risk of damage to the coating by high-energy ions.

In one variant of the method, the first gas in the gas mixture is a noble gas. Noble gases generally have comparatively high ionization energies. It is therefore favorable when the first gas in the gas mixture is a noble gas. In addition, a plasma is generally formed in a plasma source using inert gases, e.g. noble gases.

In one development, the second gas in the gas mixture is a second noble gas. The noble gases He, Ne, Ar, Kr, Xe each have different (first) ionization energies, where the ionization energy increases with increasing atomic number, meaning that He has the highest and Xe the lowest ionization energy.

In one development of this variant, the noble gas is Ar, and the further noble gas is selected from the group comprising: Kr and Xe. Plasma sources that serve to generate a plasma for plasma ion assistance are frequently operated with Ar as plasma gas. Depending on the type of plasma source, it may therefore be favorable when the noble gas is Ar, since the plasma source may have been designed or optimized for operation with Ar.

In an alternative development of this variant, the noble gas is Kr and the further noble gas is Xe. The article [6] stated that the degree of compaction in the deposition of the coating material is affected primarily by the transfer of momentum and not by the ion energy. Therefore, the use of heavier noble gas ions leads to a higher effect with regard to compaction than the use of lighter noble gas ions (Kr>Ar>Ne). For compaction, it may therefore be favourable when the gas mixture contains heavy noble gases or noble gas ions.

In a further alternative development, the noble gas is Ne, and the further noble gas is selected from the group comprising: Ar, Kr and Xe. The noble gas neon, by comparison with Ar, Kr and Xe, has a comparatively high first ionization energy, which is favorable for Penning ionization, since a comparatively high energy transfer is possible. Mixing with heavier noble gases such as Kr or Xe, even when the comparatively light noble gas neon is used, makes it possible to achieve a comparatively high transfer of momentum to the coating material and hence high compaction of the coating material.

In a further variant, the second gas is a reactive gas. A gas mixture of a noble gas and a reactive gas having a lower ionization energy than the noble gas may also be favorable for the assistance of deposition of the coating material. The reactive gas may, for example, be a fluorine-containing gas, but it is also possible to use other reactive gases, for example oxygen or ozone.

The gas mixture may, for example, be a mixture of krypton (ionization energy 14 eV) and NF₃ (ionization energy 13 eV) or xenon (ionization energy 12.1 eV) and tetrafluoroethylene C₂F₄ (ionization energy 10.1 eV). Also possible in principle are other gas mixtures containing a noble gas as first gas and a reactive gas as second gas, provided that the ionization energy of the reactive gas is lower than the ionization energy of the noble gas. The ionization energies of a multitude of chemical elements or compounds can be looked up, for example, in Lias, S. G. & Liebman, J. F. Ion Energetics Data. NIST Chemistry WebBook, NIST Standard Reference Database Number 69. 165-220 (2009) or at “https://www.cup.uni-muenchen.de/ph/aks/wanner/newhome/uploads/Main/Ionisierungsenergien_Tabelle.pdf”.

The second gas in the gas mixture of the first gas and the second gas is typically present in a proportion of less than 10% by volume, of less than 1% by volume or of less than 0.1% by volume. It will be apparent that there may in principle be more than two gases present in the gas mixture, in particular more than two noble gases.

In a further variant, the gas mixture includes a third gas, or a third gas is added to the gas mixture. The third gas is preferably selected from the group comprising: O₂, N₂ and fluorine-containing gases. The third gas, for example a fluorine-containing gas, may serve to perform deposition of the coating material in a fluoridic atmosphere. The fluorine-containing gas may, for example, be a gas selected from the group comprising: F₂, CF₄, SF₆, xenon fluorides, for example XeF₂, XeF₄, XeF₆, NF₃, HF, BF₃, CH₃F, C₂F₄.

In one development, the third gas is added to the gas mixture in a proportion of less than 2% by volume, preferably of less than 1% by volume, more preferably of less than 0.01% by volume, even more preferably of less than 0.001% by volume, in particular of less than 0.001% by volume. In general, it is favorable when only a small proportion of the third gas is added to the gas mixture.

The plasma is generated in a plasma source. It is generally the case that only one gas, for example a noble gas, is fed to a conventional plasma source for the generation of the plasma. An ionization space is typically formed within the plasma source, in which the gas supplied is ionized and a plasma is formed. There are various ways of generating a plasma that assists deposition from the gas mixture described further up:

In one variant, the first gas and the second gas and/or the gas mixture is introduced via at least one gas inlet into a plasma source in which the plasma is generated. It is possible to form the gas mixture before it is fed via a gas inlet to the plasma source or the ionization space. If the plasma source has two or more gas inlets, the first gas may be fed to a first gas inlet and the second gas to a second gas inlet. In that case, the gas mixture is formed only within the plasma source. A plasma source having two gas inlets for supply of gases is described, for example, in article [7].

In an alternative variant, the gas mixture is formed by introducing the first gas via a gas inlet into a plasma source in which the plasma is generated, and introducing the second gas into a vacuum chamber in which the substrate is disposed, or vice versa, meaning that the second gas is introduced via the gas inlet into the plasma source and the first gas is introduced into the vacuum chamber.

In that case, the gas mixture is formed only outside the plasma source in the vacuum chamber in which the coating with the coating material takes place. It is favorable when the first/second gas is fed into the vacuum chamber close to the plasma source, more specifically close to an exit opening of the plasma source. This purpose may be served, for example, by a gas shower disposed immediately adjacent to the exit opening of the plasma source, as described in article [7]. This supply of the second gas outside the plasma source is favorable especially if the second gas is a reactive gas, since the admission or supply of the second gas into the plasma source can lead to degradation of the cathode or of other components of the plasma source.

In a further variant, a coating rate or vapor deposition rate in the deposition of the coating material is less than 10⁻¹⁰ m/s. As described further up in connection with equation (1), it is possible by reducing the coating rate or the number N_{M} of incident coating molecules per unit time to increase the energy per molecule EPM. However, the coating rate chosen should not be too small since any residual gases present in the vacuum chamber will otherwise be introduced into the deposited coating material. A small coating rate also enables generation of an essentially constant degree of compaction in the deposition, i.e. one that is only slightly dependent, if at all, on the angle of vapor deposition.

In a further embodiment, an active ion energy of ions present in the plasma is less than 100 eV, preferably between 45 eV and 100 eV. For definition of the active iron energy, reference is made to DE 10 2005 017 742 A1, the entirety of which is incorporated in the content of this application by reference. An active ion energy within the above-specified order of magnitude has been found to be favorable for the deposition of dense layers, as also apparent, for example, from FIG. 1 of article [3]. If ion energies greater than 100 eV are used in the deposition, there will generally be an increase in damage to the coating by high-energy ions. If the active ion energy is too low, the degree of compaction will decrease.

In a further variant, the substrate is selected from the group comprising: fluidic materials, preferably metal fluorides, in particular alkaline earth metal fluorides. As described further up, for applications in the DUV wavelength range at wavelengths of less than 250 nm or 200 nm, substrates used for transmitting optical elements are frequently metal fluorides, in particular alkaline earth metal fluorides, for example fluorspar (CaF₂) or magnesium fluoride (MgF₂), since these materials are transparent at wavelengths of less than 250 nm. It will be apparent that the method described further up can in principle also be applied to other substrates, for example to substrates of quartz glass (SiO₂).

The coating material can be deposited, for example, with the aid of a PVD (physical vapor deposition) method. For example, the coating material can be deposited by thermal evaporation, in particular by electron beam evaporation. It is likewise possible to use other methods of depositing a coating material, e.g. sputtering. In principle, in the process described here, it is possible to employ any deposition methods in which plasma ion assistance is possible or viable. However, the temperature chosen in the deposition should not be too high and should generally not exceed about 200° C.

The coating material may, for example, be an oxidic material, e.g. SiO₂, or a fluoridic material, e.g. MgF₂. It will be apparent that it is also possible to use other materials to form a layer of the coating.

A further aspect of the invention relates to an optical element comprising: a substrate, preferably composed of a fluoridic material, in particular composed of a metal fluoride, wherein the substrate has a coating comprising at least one layer formed by the method described further up. The material of the substrate may be quartz glass (SiO₂), for example. If the substrate is formed from a fluoridic material, the material may, for example, be CaF₂ or MgF₂. The substrate may take the form of a planar sheet, but it may also be a curved substrate. Correspondingly, the surface of the substrate to which the layer or coating is applied may also be planar or curved.

The coating may include one or more layers which may contain, for example, an oxidic material or a fluoridic material. It is not absolutely necessary for all layers of the coating to be applied to the substrate with the aid of plasma ion assistance by the method described further up. Instead, it is possible that individual layers are not to be compacted, as described in EP3111257 B1 cited further up. In general, however, it is advantageous when all layers of the coating are applied with the aid of the method described further up in order to achieve maximum compaction.

The coating may take the form, for example, of a stack of interference layers and include two materials having a very high and very low refractive index. The coating may serve, for example, to increase or decrease the reflection of the optical element. Preference is given here to using a combination of alternating fluidic and oxidic layers, as described, for example, in U.S. Pat. No. 9,933,711 B2 or in U.S. Ser. No. 10/642,167 B2. As well as oxidic or fluoridic materials, there are also other useful coating materials, for example oxyfluorides.

A further aspect of the invention relates to an optical system, in particular for the DUV wavelength range, i.e. for wavelengths of less than 250 nm. The optical system has at least one optical element formed as described further up. The optical system may, for example, be a DUV lithography system or an inspection system, for example for inspection of a mask or wafer, but also a laser, for example an excimer laser.

Further features and advantages of the invention will be apparent from the description of working examples of the invention that follows, with reference to the figures of the drawing, which show details essential to the invention, and from the claims. The individual features may each be implemented alone or in a plurality in any combination in one variant of the invention.

### BRIEF DESCRIPTION OF THE DRAWINGS

Working examples are shown in the schematic drawing and are explained in the description which follows. The figures show:

FIG. 1 a schematic diagram of a coating apparatus for coating of substrates,

FIG. 2 a schematic diagram of the first ionization energy of a plurality of chemical elements as a function of atomic number,

FIG. 3 schematic diagrams of a degree of compaction as a function of ion energy, coating rate and angle of vapor deposition,

FIG. 4 a schematic diagram of an example of an optical element having a coating that has been applied with the coating apparatus of FIG. 1, and

FIG. 5 a schematic diagram of an example of a DUV lithography system having the optical element of FIG. 4.

### DETAILED DESCRIPTION

In the description of the drawings that follows, identical reference signs are used for components that are analogous or are the same or have the same or analogous function.

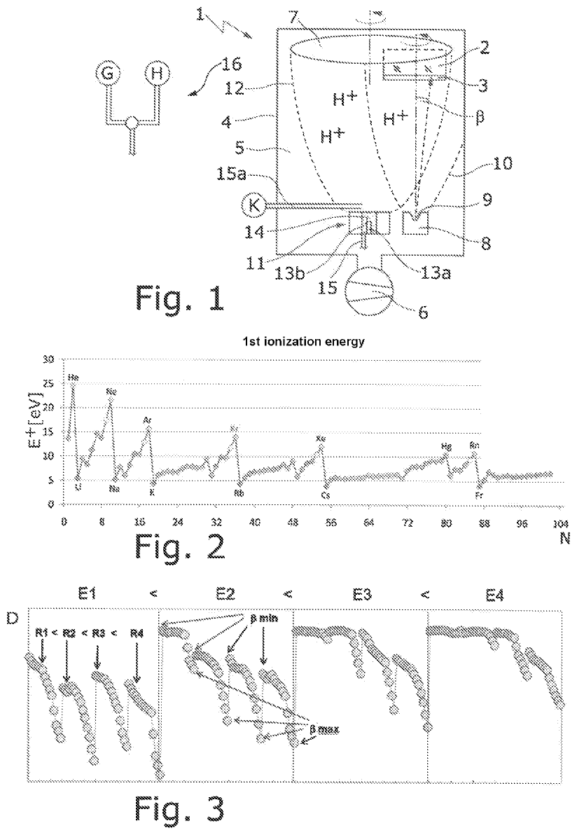

FIG. 1 shows a schematic of a coating apparatus 1 for forming or for depositing of layers—a layer 3 in the example shown—on a substrate 2. The coating apparatus 1 has a high-vacuum-tight recipient 4 surrounding a vacuum chamber 5. A turbomolecular pump 6 serves to evacuate the vacuum chamber 5. Disposed within the vacuum chamber 5 is a holding device 7 on which a plurality of substrates can be mounted, of which FIG. 1 shows just a single substrate 2. The holding device 7 is formed like a planetary system and has a main axis about which the substrates are rotated during coating, as indicated by an arrow in FIG. 1. The or a particular substrate 2 additionally rotates about its own axis of symmetry during coating, as likewise indicated by an arrow in FIG. 1. The substrate 2 in the example shown is a plane-parallel plate to which an antireflection coating is to be applied. The substrate 2 in the example shown is formed from calcium fluoride (CaF₂), but may also be formed from a different material. The material of the substrate 2 may, for example, be another fluoridic material, for example a metal fluoride, in particular an alkaline earth metal fluoride.

Within the vacuum chamber 5 is disposed an electron beam evaporator 8 into which a coating material 9 has been introduced. During the deposition, the electron beam evaporator 8 generates an evaporation cone 10 in which the substrate 2 to be coated is disposed, such that the coating material 9 can be deposited on a surface of the substrate 2 to be coated that faces the electron beam evaporator 8. The coating material 9 in the example shown is SiO₂, but it may also be another material, for example an oxidic or fluoridic material or an oxyfluoride.

Also disposed within the vacuum chamber 5 is a plasma source 11 that serves to generate a plasma 12, which is directed onto the surface of the substrate 2 to be coated in the form of a plasma jet. The plasma source 11 is a DC plasma source, as described in detail in the article [7]. The plasma source 11 has a rod-shaped cathode 13a surrounded by a ring-shaped anode 13b. An electrical field is generated between the cathode 13a and the anode 13b for generation of the plasma 12, in order to ionize a gas, more specifically a gas mixture 14, in an ionization space of the plasma source 11 and to produce the plasma 12 in this way. A coil (not shown) surrounds the anode 13b on its outside and generates an axial magnetic field in the ionization space.

As likewise apparent in FIG. 1, the gas mixture 14 is supplied to the plasma source 11 via a gas inlet 15, which, in the example shown, is disposed at the base of the ionization space of the plasma source 11. It will be apparent that the gas inlet 15 may also be positioned elsewhere in the plasma source 11 in order to supply the plasma source 11 with the gas mixture 14.

As likewise apparent in FIG. 1, the gas mixture 14 is formed in a mixing unit 16 which is likewise arranged outside the vacuum chamber 5. The mixing unit 16 has a valve arrangement in order to mix a first gas G present in a first gas reservoir with a second gas H present in a second gas reservoir. With the aid of the valve arrangement, it is optionally possible to adjust the mixing ratio of the two gases G, H, but this is not absolutely necessary. For the use described here, it is generally sufficient when the second gas H is present in the gas mixture 14 in a proportion of less than 10% by volume, of less than 1% by volume or of less than 0.1% by volume.

The gas mixture 14 is supplied to the plasma source 11 in order to generate chemoionization, i.e. transfer of excitation energy in the case of particle collisions between molecules or atoms of the first gas G and molecules or atoms of the second gas H. For the considerations that follow, it is assumed that the second gas H in the gas mixture 14 has a (first) ionization energy smaller than a (first) ionization energy of the first gas G. In this case, the Penning ionization can take place, for example, according to equations (2) and (3) given further up, meaning that, in the case of a collision, the excitation energy of the first gas G can be transferred to the second gas M such that the second gas M is ionized, or the two gases G, M may together form an ionized species, for example of the GM⁺ form.

In the example shown in FIG. 1, a third gas K is added to the gas mixture 14 including the two gases G, H. The third gas K can be added in the mixing unit 16, but it is also possible to supply the gas mixture 14 with the third gas K via a further gas inlet 15a in the plasma source 11, as shown in FIG. 1. The further gas inlet 15a is what is called a gas shower that brings the third gas K to the vicinity of, and causes it to emerge at, an outlet opening of the plasma source 11. The gas mixture 14 of the two gases G, H therefore forms at the exit of the plasma source 11 or at the exit of the ionization space.

The third gas K in the example shown is a fluoridic gas, but may also be another kind of gas, for example O₂ or N₂. In the present case, the proportion of the third gas K in the gas mixture 14 is less than 0.001% by volume. The proportion of the third gas K may alternatively be greater and may, for example, be less than 1% by volume or less than 2% by volume.

The fluoridic gas may, for example, be a gas selected from the group comprising: F₂, CF₄, SF₆, xenon fluorides, for example XeF₂, XeF₄, XeF₆, NF₃, HF, BF₃, CH₃F, C₂F₄. The third, fluoridic gas K in the present case serves to generate a fluorine-containing atmosphere in the vacuum chamber 5. Fluorination of the coating material 9 is also possible with the aid of the fluoridic gas K in the deposition onto the substrate 2, for example in order to deposit fluorinated SiO₂. It will be apparent that the third, fluoridic gas K can also serve for fluorination of other coating materials 9.

As an alternative to the supply of the gas mixture 14 via the (first) gas inlet 15, it is possible to feed in the first gas G to the plasma source 11 or the ionization space via the first gas inlet 15 and the second gas H via a second gas inlet (not shown in the image). In that case, the gas mixture 14 is formed only in the plasma source 11, more specifically in the ionization space.

Alternatively, the first gas G may be introduced into the plasma source 11 or into the ionization space, for example, via the first gas inlet 15, and the second gas H is introduced into the vacuum chamber 5 outside the plasma source 11. In that case, for example, the second gas H may be fed in via the further gas inlet 15a, which forms a gas shower, in the vicinity of the exit opening of the plasma source 11, as described further up in connection with the third gas K. In principle, the second gas H may alternatively be introduced into the vacuum chamber 5 elsewhere in order to form the gas mixture 14. It will be apparent that the roles of the first gas G and of the second gas H may also be exchanged.

The supply of the second gas H via the further gas inlet 15a is favorable in particular when the first gas G is a noble gas and the second gas H is a reactive gas, e.g. oxygen, ozone or a fluorine-containing gas. The supply of a reactive gas into the ionization space of the plasma source 11 would possibly result in damage to the components disposed therein. Supply of the second gas H via the further gas inlet 15a, which may, for example, be in ring-shaped form and have radial inlet openings, can avoid such damage. The gas mixture 14 may, for example, be a mixture of krypton (ionization energy 14 eV) and NF₃ (ionization energy 13 eV) or xenon (ionization energy 12.1 eV) and tetrafluoroethylene C₂F₄ (ionization energy 10.1 eV), but it is also possible to use other kinds of gas mixtures 14.

The first gas G and the second gas N may also be noble gases, for which FIG. 2 shows the (first) ionization energy E⁺ (in eV) as a function of atomic number N. For the first ionization energy E⁺ of the noble gases, the order is as follows (from the greatest to the smallest ionization energy): He, Ne, Ar, Kr, Xe.

There are various options for the choice of the two noble gases G, H in the gas mixture 14: For example, the first gas G may be Ar, and the second gas H may be Kr or Xe. The use of a gas mixture 14 containing Ar is favorable since the plasma source 11 shown in FIG. 1 is designed for operation with Ar. In particular, a gas mixture of Ar and Kr has been found to be favorable.

Alternatively, it is possible that the first gas G in the gas mixture 14 is Ne and the second gas H in the gas mixture 14 is selected from the group comprising: Ar, Kr and Xe. If the second gas H is Ar, the result is the classic example of Penning ionization (E⁺(Ne)=16.5 eV, E⁺(Ar)=15.8 eV, i.e. E⁺(Ne)>E⁺(Ar)):

Ne*+Ar→Ar⁺+e⁻+Ne (4)

Alternatively, the gas mixture 14 may contain krypton as the first noble gas G and xenon as the second noble gas H. This is favorable since the degree of compaction of layer 3 is affected primarily by the transfer of momentum from the ions H⁺ present in the plasma 12 and not by the ion energy. Therefore, the use of heavier noble gases in the gas mixture 14 generally leads to greater compaction than is the case for lighter noble gases.

As apparent in FIG. 3, the degree of compaction D (in arbitrary units) also depends on other parameters, for example on the ion energy E, the rate of vapor deposition or coating R, and angle of vapor deposition β (cf. FIG. 1). The four diagrams shown in FIG. 3 differ by the ion energy E, which increases from left to right (E1 to E4). The diagrams shown in FIG. 3 each show the degree of compaction for four coating rates R1 to R4, increasing from left to right. For a respective coating rate R1 to R4, the dependence of the degree of compaction on the angle of vapor deposition β is shown. As apparent in FIG. 3, the degree of compaction decreases proceeding from a minimum angle of vapor deposition βₘᵢₙ up to a maximum angle of vapor deposition βₘᵢₙ, in most diagrams.

It has been found to be favorable when the coating rate R in the deposition of the coating material 9 is less than 10⁻¹⁰ m/s. This is favorable firstly because the energy per molecule EPM increases with decreasing coating rate R, as apparent from equation (1). This is likewise favorable because, at low coating rates R, the degree of compaction is essentially constant or independent of the vapor deposition angle. But the coating rate R chosen should not be too small in order to avoid introduction of any residual gases present in the vacuum chamber 5 into the deposited coating material 9.

As apparent, for example, from FIG. 1 of article [3], it is favorable for the degree of compaction when the active ion energy E is less than about 100 eV. Favorable values for the active ion energy E of the ions H⁺ present in the plasma 12 are within an interval between about 60 eV and about 100 eV.

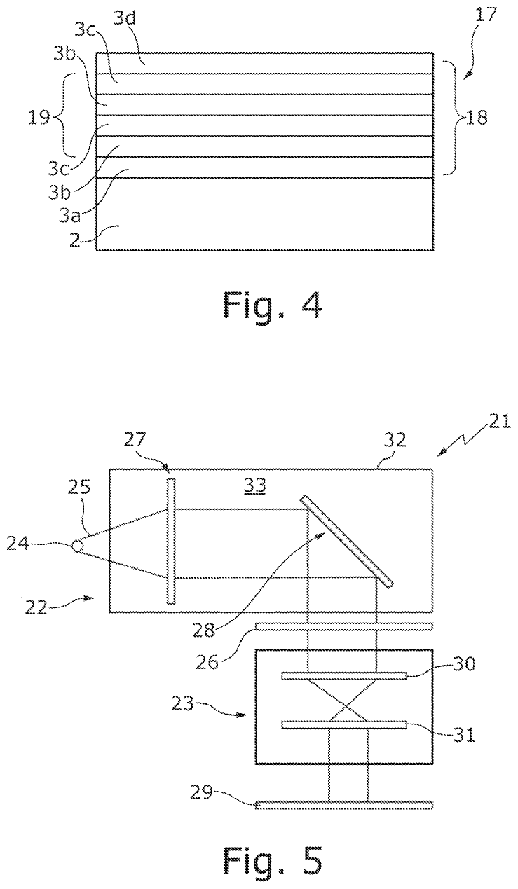

FIG. 4 shows an optical element 17 to which all layers 3 of a coating 18 have been applied in the manner described further up in the coating apparatus 1 of FIG. 1. The design of the optical element 17 in the example shown in FIG. 4 is as described in the above citation U.S. Pat. No. 9,933,711 B2 or U.S. Ser. No. 10/642,167 B2. But it will be apparent that the design of the optical element 17 or coating 18 may also be different.

The optical element 17 has a substrate 2 composed of CaF₂. A first layer 3a composed of a fluoride compound of low refractive index is applied to the substrate 2. The first layer 3a can be applied directly to the substrate 2, but it is also possible that an adhesion promoter layer or another kind of functional layer is applied between the substrate 2 and the first layer 3a. The coating 18 additionally comprises a layer system 19 disposed between the first layer 3a and a last layer 3d of the coating 18. The last layer 3d in the example shown is an oxide compound.

The layer system 19 in the example shown in FIG. 4 has two pairs of alternating layers 3b, 3c, which respectively include a fluoride compound and an oxide compound. The layer 3b adjacent to the first layer 3a in the layer system 19 includes an oxide compound; the layer 3c applied to the layer 3b includes a fluoride compound. The entire coating 18 therefore consists of an alternating sequence of three fluoridic and oxidic layers 3a-d. The material of the oxidic layers 3b, 3d may, for example, be SiO₂, etc.; the material of the fluoridic layers 3a, 3c may, for example, be AlF₃, MgF₂, etc. As an alternative to the optical element 17 shown in FIG. 4, the coating 18 may also have an odd number of layers. In that case, the first layer and the last layer may, for example, be oxidic layers, such that an alternating sequence of oxidic layers and fluoridic layers within the coating 18 may be maintained.

The coating 18 shown in FIG. 4 serves as antireflection coating for avoidance of the reflection of DUV radiation at the surface of the substrate 2 to which the coating 18 is applied. It will be apparent that the substrate 2 may also have a corresponding coating 18 on the opposite side. The substrate 2 may also be formed from a material other than a fluoridic material, for example from quartz glass (SiO₂).

FIG. 5 shows a schematic of an optical system 21 in the form of a DUV lithography apparatus at wavelengths of less than 250 nm, in particular for wavelengths in the range between 100 nm and 200 nm or 190 nm. The DUV lithography apparatus 21 has, as essential components, two optical systems in the form of an illumination system 22 and a projection system 23. For the performance of an exposure process, the DUV lithography apparatus 21 has a radiation source 24 which may, for example, be an excimer laser which emits radiation 25 at a wavelength in the DUV wavelength range of, for example, 193 nm, 157 nm or 126 nm and may be an integral part of the DUV lithography apparatus 21.

The radiation 25 emitted by the radiation source 24 is conditioned with the aid of the illumination system 22 such that a mask 26, also called a reticle, can be illuminated thereby. In the example shown in FIG. 5, the exposure system 22 has both transmitting and reflecting optical elements. In a representative manner, FIG. 5 shows a transmissive optical element 27, which focuses the radiation 25, and a reflective optical element 28, which deflects the radiation 25, for example. In a known manner, in the illumination system 22, a wide variety of transmitting, reflecting or other optical elements can be combined with one another in any manner, even in a more complex manner.

The mask 26 has, on its surface, a structure which is transferred to an optical element 29 to be exposed, for example a wafer, with the aid of the projection system 23 in the context of production of semiconductor components. In the example shown, the mask 26 is designed as a transmitting optical element. In alternative executions, the mask 26 may also be designed as a reflective optical element. The projection system 22 has at least one transmitting optical element in the example shown. The example shown illustrates, in a representative manner, two transmitting optical elements 30, 31, which serve, for example, to reduce the structures on the mask 26 to the size desired for the exposure of the wafer 29. In the case of the projection system 23 as well, it is possible for reflective optical elements among others to be provided, and for any optical elements to be combined with one another as desired in a known manner. It should be pointed out that optical arrangements without transmissive optical elements can also be used for DUV lithography.

The optical element 17 shown in FIG. 4 may, for example, be a transmitting optical element 27 of the exposure system 22, or the mask 26, or a transmitting optical element 30, 31 of the projection system 23 of the DUV lithography system 21.

As an alternative to the optical system 21 shown in FIG. 5 in the form of the DUV lithography system, it is also possible for another optical system, in particular for the DUV wavelength range, to include at least one optical element 17 as shown in FIG. 4. The optical system 21 may, for example, be a wafer inspection system or a mask inspection system. The excimer laser 24 may also comprise an optical element 17 comprising a substrate 2 with a coating 18 applied in the manner described above. The optical element 17 may, for example, be an exit window of a laser chamber.

In summary, in the manner described above, layers 3, 3a-d or a coating 18 may be deposited on a substrate 2 of an optical element 17, which ensures a high degree of compaction, combined with a long lifetime or high radiation resistance of the optical element 17 even in the case of irradiation at high radiation intensities.

### REFERENCES

[1] U. Natura, S. Rix, M. Letz, L. Parthier, “Study of haze in 193 nm high dose irradiated CaF₂ crystals”, Proc. SPIE 7504, Laser-Induced Damage in Optical Materials: 2009, 75041P (2009).
[2] M. Bischoff, O. Stenzel, K. Friedrich, S. Wilbrandt, D. Gabler, S. Mewes, and N. Kaiser, “Plasma-assisted deposition of metal fluoride coatings and modeling the extinction coefficient of as-deposited single layers”, Appl. Opt. 50 (2011) C232-C238.
[3] R. Kaneriya, R. R. Willey, K. Patel, “Improved Magnesium Fluoride Process by Ion-Assisted Deposition”, Proc. Soc. Vac. Coat. 53 (2010) 313-319.
[4] J. Targove et al., “Ion-assisted deposition of lanthanum fluoride thin films”, Appl. Opt. 26 (1987) 3733-3737.
[5] M. J. Shaw, “Penning ionization”, Contemporary Physics, 15 (1974), 445-464.
[6] J. Targove and H. A. Macleod, “Verification of momentum transfer as the dominant densifying mechanism in ion-assisted deposition”, Appl. Opt. 27 (1988) 3779-3781.
[7] J. Harhausen, R. P. Brinkmann, R. Foest, M. Hannemann, A. Ohl and B. Schroder, “On plasma ion beam formation in the Advanced Plasma Source”, Plasma Sources Sci. Technol. 21 (2012) 035012.

What is claimed is:

1. A method of forming at least one layer on a substrate made of a fluoridic material, comprising:
depositing at least one coating material on the substrate to form the layer, and
generating a plasma to assist said depositing of the coating material,
wherein the plasma is formed from a gas mixture containing a first gas and a second gas,
wherein the second gas has an ionization energy less than an ionization energy of the first gas, wherein the first gas is a noble gas, and wherein the second gas is a further noble gas.

2. The method as claimed in claim 1, wherein the noble gas is Ar and the further noble gas is selected from the group consisting essentially of: Kr and Xe.

3. The method as claimed in claim 1, wherein the noble gas is Kr and the further noble gas is Xe.

4. The method as claimed in claim 1, wherein the noble gas is Ne and the further noble gas is selected from the group consisting essentially of: Ar, Kr and Xe.

5. The method as claimed in claim 1, wherein said generating comprises adding a third gas to the gas mixture.

6. The method as claimed in claim 5, wherein the third gas is selected from the group consisting essentially of: O₂, N₂, O₃, N₂O, H₂O₂, and fluorine-containing gases.

7. The method as claimed in claim 5, wherein the third gas is added to the gas mixture in a proportion of less than 2% by volume.

8. The method as claimed in claim 7, wherein the third gas is added to the gas mixture in a proportion of less than 0.1% by volume.

9. The method as claimed in claim 7, wherein the third gas is added to the gas mixture in a proportion of less than 0.001% by volume.

10. The method as claimed in claim 1, wherein the first gas and the second gas and/or the gas mixture are/is introduced via at least one gas inlet into a plasma source in which the plasma is generated.

11. The method as claimed in claim 1, wherein the gas mixture is formed by
introducing the first gas via a gas inlet into a plasma source in which the plasma is generated, and in which the second gas is introduced into a vacuum chamber in which the substrate is disposed, or
introducing the second gas via the gas inlet into the plasma source in which the plasma is generated, and in which the first gas is introduced into the vacuum chamber in which the substrate is disposed.

12. The method as claimed in claim 1, wherein a coating rate in depositing the coating material is less than 10⁻¹⁰ m/s.

13. The method as claimed in claim 1, wherein an active ion energy of ions present in the plasma is less than 100 eV.

14. The method as claimed in claim 13, wherein the active ion energy of the ions present in the plasma is between 45 eV and 100 eV.

15. The method as claimed in claim 1, wherein the substrate is a metal fluoride.

16. The method as claimed in claim 15, wherein the substrate is an alkaline earth metal fluoride.

17. An optical element comprising:
a substrate composed of a fluoridic material,
a coating on the substrate that comprises at least one layer formed by the method as claimed in claim 1.

18. The optical element as claimed in claim 17, wherein the substrate is composed of a metal fluoride.

19. An optical system, comprising:
a radiation source,
an illumination system, a mask, and a projection system,
wherein the illumination system is configured to illuminate the mask with radiation from the radiation source, and the projection system is configured to project the radiation of the illuminated mask onto a wafer, and
wherein at least one of the illumination system, the mask and the projection system comprises at least one optical element as claimed in claim 17.

20. The optical system as claimed in claim 17 and configured for operation in a deep-ultraviolet (DUV) wavelength range.
